(19) United States
(12) Patent Application Publication
(10) Pub. No.: US 2019/0351511 A1
(43) Pub. Date: Nov. 21, 2019

(54) LASER SCRIBING DEVICE

(71) Applicant: QMC. INC., Anyang-si (KR)

(72) Inventors: Beng So RYU, Incheon (KR); Hark Yong KIM, Seoul (KR); Gwan Yoo KIM, Cheongju-si (KR); Dong Woo SHIN, Jincheon-gun (KR); Seong Ho SONG, Bucheon-si (KR); Jang Hyun KIM, Seoul (KR)

(21) Appl. No.: 16/525,614

(22) Filed: Jul. 30, 2019

Related U.S. Application Data
(63) Continuation of application No. PCT/KR2018/002082, filed on Feb. 20, 2018.

(30) Foreign Application Priority Data
Feb. 20, 2017 (KR) 10-2017-0022268

(51) Int. Cl. B23K 26/364; B23K 26/06; B23K 26/067; B23K 26/064

(52) U.S. Cl. CPC B23K 26/364; B23K 26/0604; B23K 26/0626; B23K 26/064; B23K 26/067

(57) ABSTRACT

Provided is a laser scribing device including: a laser light source for outputting a laser beam; a splitter for dividing the laser beam into a first laser beam and a second laser beam; a beam expander telescope for adjusting a divergent angle on a path of the first laser beam or a path of the second laser beam; a beam combiner for combining the first laser beam and the second laser beam; and a light-collecting lens for light-collecting the first and second laser beams that are combined by the beam combiner, wherein the first laser beam and the second laser beam have different focal distances.

### CROSS-REFERENCE TO RELATED APPLICATIONS

This application claims priority under 35 U.S.C. § 119 to Korean Patent Application No. 10-2017-0022268, filed on Feb. 20, 2017, in the Korean Intellectual Property Office, the disclosure of which is incorporated herein by reference in its entirety.

### TECHNICAL FIELD

The following disclosure relates to a laser scribing device.

### BACKGROUND

A light emitting diode (LED) is used for electronic components such as cell phone switch, back light unit (BLU) for LED TV, and the like, due to low power, high durability, high brightness, fast response speed, environmentally friendly characteristics, and the like. As the application range of LED is expanded to the field of lighting, the amount of use is increasing every year.

A LED manufacturing process is largely divided into an EPI process that grows indium gallium nitride (InGaN), a chip production process, a packaging process, and a modularization process. In addition, among the chip production process, scribing is a process for cutting a chip, which is an important process in which characteristics and a production amount of the chip are determined according to a processing method.

In particular, defects such as reverse current (IR), double chip, meandering, chipping, and the like, which are generated during the scribing process, act as a factor that deteriorates a production yield of the LED chip and makes optimization and quantification of the process difficult.

In addition, in the conventional method, the cutting is performed by using a diamond tip. However, there have been serious problems such as poor appearance of the chip, low productivity, and high processing cost. Thus, a number of LED manufacturers are increasingly using a scribing device using laser.

The laser scribing is a process of cutting a wafer or a substrate or a process of producing a cutting line on a chip-by-chip basis, and is used in an LED industry employing a high-strength sapphire wafer and a package industry employing a ceramic substrate.

In this regard, Korean Patent Laid-Open Publication No. 10-2004-0100042 (title of the invention: scribing apparatus using laser beam) discloses a configuration including a table on which an object to be processed with laser is displaced; a laser oscillator for emitting a laser beam to the object to be processed on the table; a light-collecting lens installed at an upper portion of the table and irradiating the object to be processed with the laser beam transmitted from the laser oscillator; and a beam delivery device connected between the laser oscillator and the light-collecting lens to transfer the laser beam emitted from the laser oscillator to a head.

However, such conventional scribing devices have a problem that there is a limitation in processing a thick object to be processed.

### SUMMARY

An embodiment of the present disclosure is directed to providing a laser scribing device for irradiating an object to be processed with two laser beams having different focal distances.

Meanwhile, the technical problem to be achieved by the present embodiment is not limited to the above-described technical problems, and other technical problems may be present.

In one general aspect, a laser scribing device includes: a laser light source for outputting a laser beam; a splitter for dividing the laser beam into a first laser beam and a second laser beam; a beam expander telescope for adjusting a divergent angle on a path of the first laser beam or a path of the second laser beam; a beam combiner for combining the first laser beam and the second laser beam; and a light-collecting lens for light-collecting the first and second laser beams that are combined by the beam combiner. Here, the first laser beam and the second laser beam have different focal distances.

### BRIEF DESCRIPTION OF THE DRAWINGS

FIG. 1 shows a laser scribing device according to a first embodiment of the present disclosure.

FIG. 2 shows a laser scribing device according to a second embodiment of the present disclosure.

FIG. 3 shows a laser scribing device according to a third embodiment of the present disclosure.

FIG. 4 shows a laser scribing device according to a fourth embodiment of the present disclosure.

FIG. 5 shows a laser scribing device according to a fifth embodiment of the present disclosure.

FIG. 6 shows a laser scribing device according to a sixth embodiment of the present disclosure.

FIG. 7 shows a laser scribing device according to a seventh embodiment of the present disclosure.

FIG. 8 shows a laser scribing device according to an eighth embodiment of the present disclosure.

FIG. 9 shows a laser scribing device according to a ninth embodiment of the present disclosure.

FIG. 10 shows a laser scribing device according to a tenth embodiment of the present disclosure.

FIG. 11 shows a laser scribing device according to an eleventh embodiment of the present disclosure.

FIG. 12 shows a laser scribing device according to a twelfth embodiment of the present disclosure.

FIG. 13 shows a laser scribing device according to a thirteenth embodiment of the present disclosure.

FIG. 14 shows a laser scribing device according to a fourteenth embodiment of the present disclosure.

FIG. 15 shows a laser scribing device according to a fifteenth embodiment of the present disclosure.

FIG. 16 shows a laser scribing device according to a sixteenth embodiment of the present disclosure.

FIG. 17 shows a laser scribing device according to a seventeenth embodiment of the present disclosure.

FIG. 18 shows a laser scribing device according to an eighteenth embodiment of the present disclosure.

FIG. 19 shows a laser scribing device according to a nineteenth embodiment of the present disclosure.

FIG. 20 shows a laser scribing device according to a twentieth embodiment of the present disclosure.

FIG. 21 is an image of an internal crack line formed inside a substrate using the laser scribing device of the present disclosure.

### DETAILED DESCRIPTION OF MAIN ELEMENTS

10: laser scribing device
100: laser light source, 200: splitter
320: first wave plate, 330: second wave plate
400: beam expander telescope
500: beam combiner, 600: light-collecting lens
700: damper
L1: first laser beam, L2: second laser beam
M1 and M2: mirror parts

### DETAILED DESCRIPTION OF EMBODIMENTS

Hereinafter, embodiments of the present disclosure will be described in detail with reference to the accompanying drawings so as to be easily practiced by those skilled in the art in the technical field to which the present disclosure pertains. It should be understood, however, that the present disclosure may be embodied in many different forms and should not be construed as limited to the embodiments set forth herein. Further, in the accompanying drawings, portions unrelated to the description are omitted in order to obviously describe the present disclosure, and similar reference numerals are used to describe similar portions throughout the present specification.

Throughout the present specification, a case where any one part is “connected” with the other part includes not only a case where the parts are “directly connected” with each other but also a case where the parts are “electrically connected” with each other with another element interposed therebetween.

Throughout the present specification, a case where any one member is positioned on the other member includes not only a case where any one member is in contact with the other member but also a case where a member is present between the two members.

Throughout the present specification, unless explicitly described to the contrary, a case where some portions “include” some elements will be understood to imply further inclusion of any other elements rather than exclusion thereof. The terms “about”, “substantially”, and the like, used throughout the present specification are used to have the meaning close to the numerical value when the manufacture and material tolerances inherent in the above-described meanings are presented, and are used to prevent the disclosure statement with an exact or absolute number provided for assisting in understanding the present specification from unauthorized use by unscrupulous infringer.

The “step to” or “step of” used throughout the present specification does not mean “step for”.

The present disclosure relates to a laser scribing device 10.

For example, in the laser scribing device 10, a laser beam emitted from a laser light source 100 is focused on a surface or an inside of an object to be processed by a first focus F1 through a light-collecting lens 600, and the laser beam is focused on the surface or the inside of the object to be processed by a second focus F2 through the light-collecting lens 600. Here, positions of the first focus and the second focus are formed differently by making divergent angles of a first laser beam and a second laser beam different. Further, as the object to be processed, a substrate having a high transmittance with respect to laser wavelength is generally used. For example, the object to be processed may be a sapphire substrate, a glass substrate, or the like, but the present disclosure is not limited thereto.

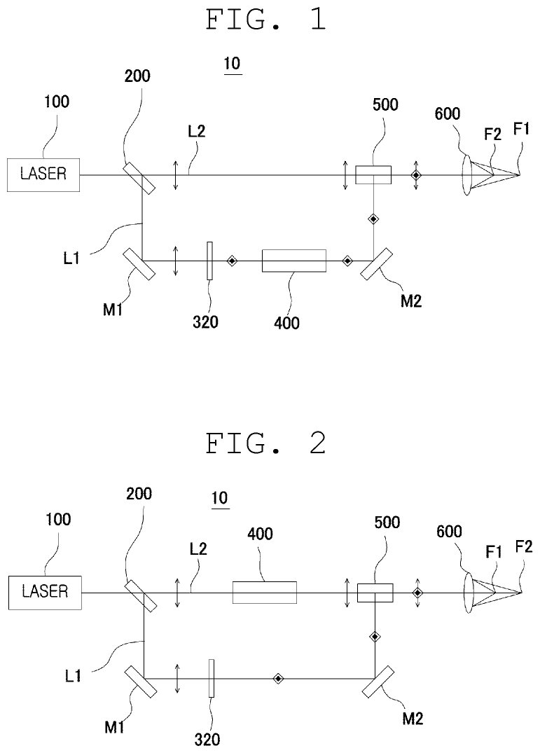

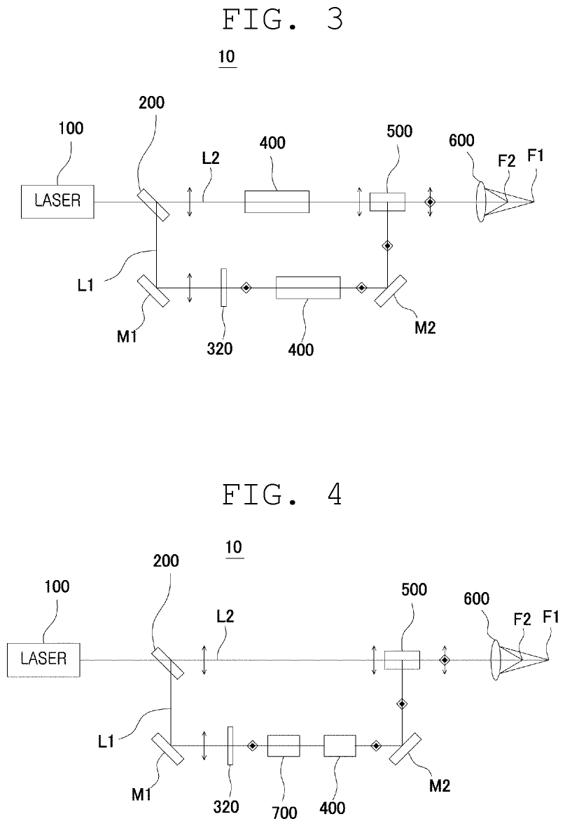

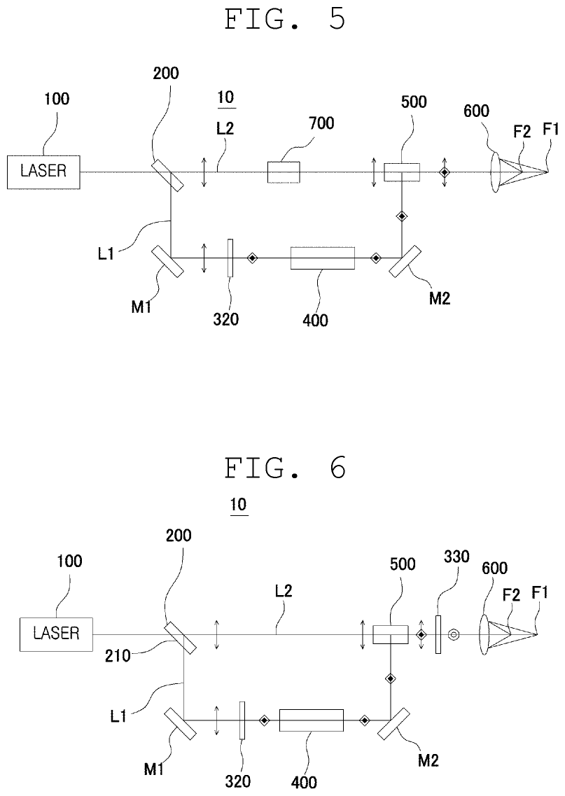

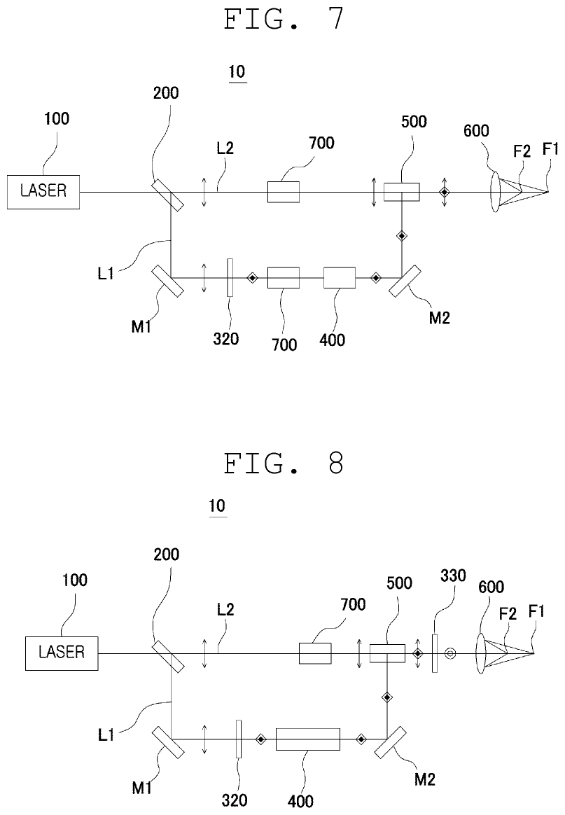

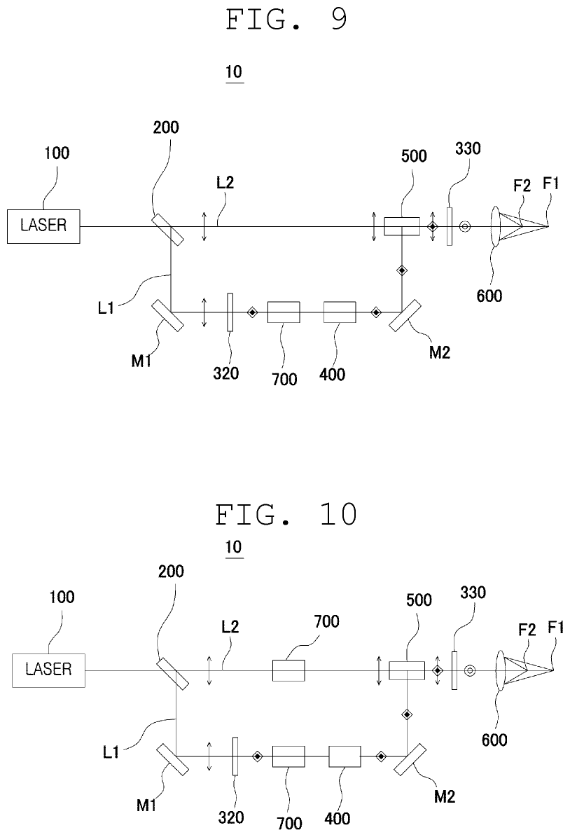

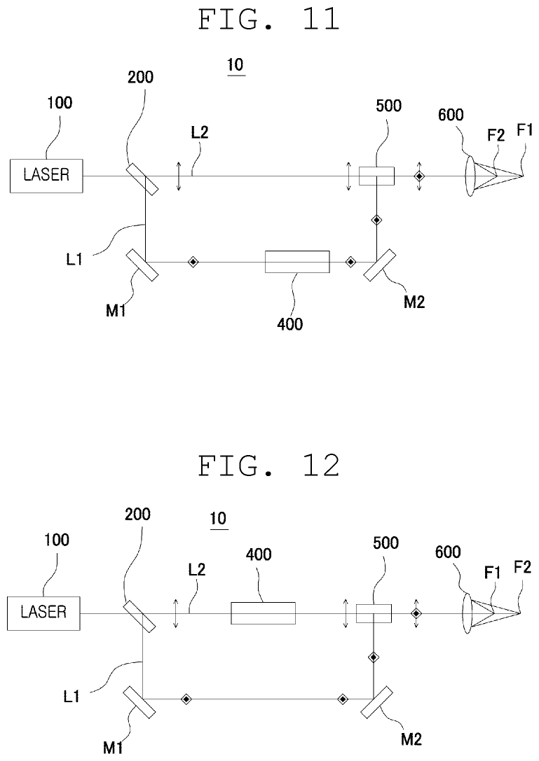

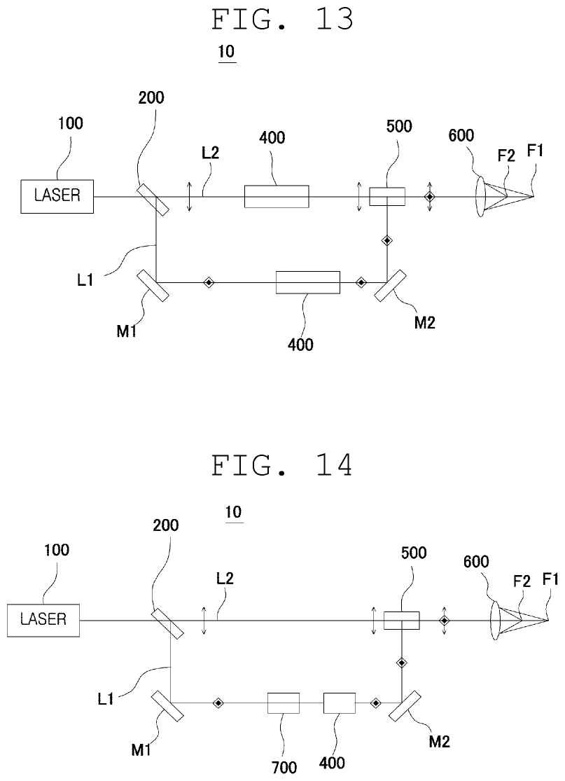

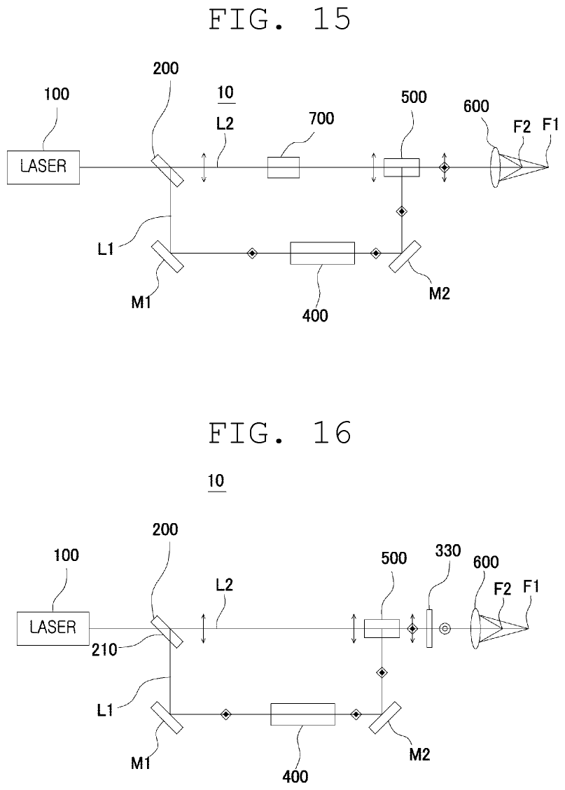

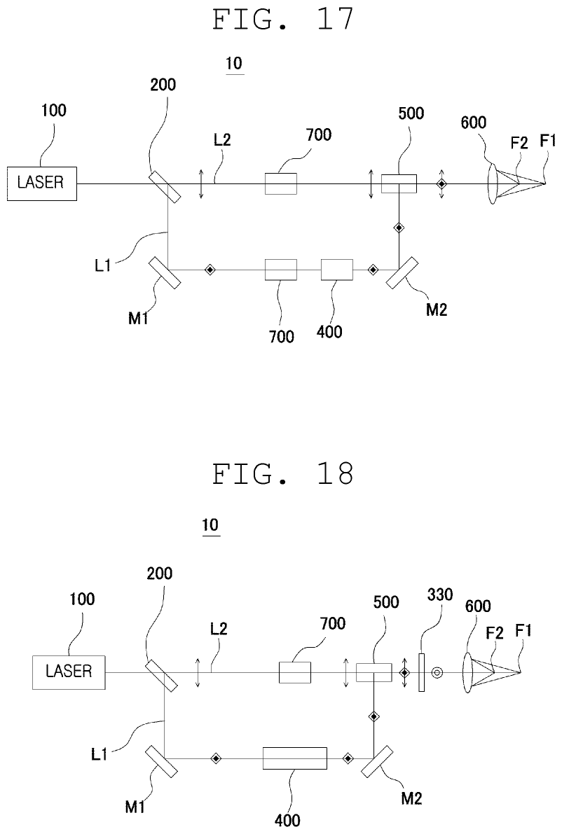

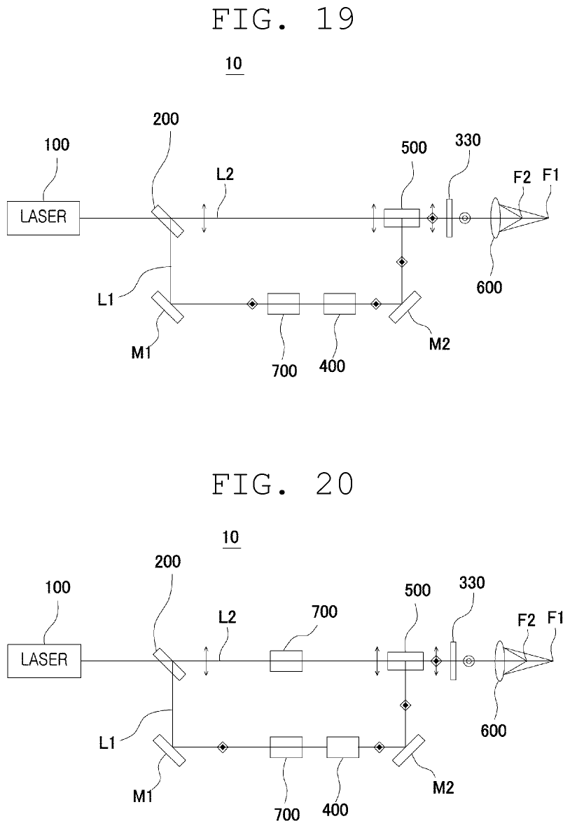

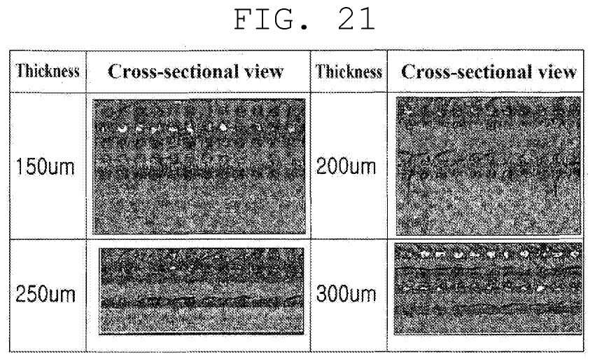

FIG. 1 shows a laser scribing device 10 according to a first embodiment of the present disclosure. FIG. 2 shows a laser scribing device 10 according to a second embodiment of the present disclosure. FIG. 3 shows a laser scribing device 10 according to a third embodiment of the present disclosure. FIG. 4 shows a laser scribing device 10 according to a fourth embodiment of the present disclosure. FIG. 5 shows a laser scribing device 10 according to a fifth embodiment of the present disclosure. FIG. 6 shows a laser scribing device 10 according to a sixth embodiment of the present disclosure. FIG. 7 shows a laser scribing device 10 according to a seventh embodiment of the present disclosure. FIG. 8 shows a laser scribing device 10 according to an eighth embodiment of the present disclosure. FIG. 9 shows a laser scribing device 10 according to a ninth embodiment of the present disclosure. FIG. 10 shows a laser scribing device 10 according to a tenth embodiment of the present disclosure. FIG. 11 shows a laser scribing device 10 according to an eleventh embodiment of the present disclosure. FIG. 12 shows a laser scribing device 10 according to a twelfth embodiment of the present disclosure. FIG. 13 shows a laser scribing device 10 according to a thirteenth embodiment of the present disclosure. FIG. 14 shows a laser scribing device 10 according to a fourteenth embodiment of the present disclosure. FIG. 15 shows a laser scribing device 10 according to a fifteenth embodiment of the present disclosure. FIG. 16 shows a laser scribing device 10 according to a sixteenth embodiment of the present disclosure. FIG. 17 shows a laser scribing device 10 according to a seventeenth embodiment of the present disclosure. FIG. 18 shows a laser scribing device 10 according to an eighteenth embodiment of the present disclosure. FIG. 19 shows a laser scribing device 10 according to a nineteenth embodiment of the present disclosure. FIG. 20 shows a laser scribing device 10 according to a twentieth embodiment of the present disclosure. FIG. 21 is an image of an internal crack line formed inside a substrate using the laser scribing device 10 of the present disclosure.

Hereinafter, the laser scribing device 10 of the present disclosure is described.

Referring to FIGS. 1 to 3, the laser scribing device 10 includes a laser light source 100 for outputting a laser beam; a splitter 200 for dividing the laser beam into a first laser beam L1 and a second laser beam L2; a wave plate 320 rotating a polarization direction of the first laser beam L1 divided by the splitter 200, by 90 degrees; a beam expander telescope 400 for adjusting a divergent angle of the first laser beam L1 or the second laser beam L2; a beam combiner 500 for combining the first laser beam L1 and the second laser beam L2; and a light-collecting lens 600 for light-collecting the first and second laser beams L1 and L2 that are combined by the beam combiner 500. Here, focal distances of the first laser beam L1 and the second laser beam L2 are different.

Further, the first laser beam L1 may be in a vertically polarized state (S-polarized light) and the second laser beam L2 may be in a horizontally polarized state (P-polarized light). For reference, in FIGS. 1 to 20, [symbol] denotes the S-polarized light vertical to a light axis, and [symbol] denotes the P-polarized light horizontal to the light axis.

For example, the laser beam output from the laser light source 100 may be a P-polarized laser. Further, the laser beam output from the laser light source 100 may be divided into a P-polarized first laser beam L1 and a P-polarized second laser beam L2 while passing through the splitter 200.

Further, the P-polarized first laser beam L1 passes through the first wave plate 320, and a polarization direction of the beam is rotated by 90 degrees to the S polarization.

Further, referring to FIGS. 1 and 2, the divergent angle of the first laser beam L1 or the second laser beam L2 may be adjusted by the beam expander telescope 400. In other words, when the laser beam is diverged through the beam expander telescope 400 (divergence beam), the focal distance becomes long, and when the laser beam is converged (convergence beam) after passing through a collimated beam state, the focal distance becomes short.

Referring to FIG. 3, the beam expander telescope 400 may be positioned in a path of the first laser beam L1 and a path of the second laser beam L2, respectively, and each beam expander telescope 400 may adjust the focal position of the first laser beam L1 and the second laser beam L2 in the object to be processed.

To this end, the beam expander telescope 400 may include at least two or more lenses. Further, by adjusting the distance between the lenses of the beam expander telescope 400 positioned on the path of the first laser beam L1 or the second laser beam L2, an angle (convergence angle and the divergence angle) of the laser beam incident on the light-collecting lens 600 may be changed, and thus the focal position of the first laser beam L1 or the second laser beam L2 may be changed.

In addition, the first laser beam L1 and the second laser beam L2 are combined while passing through the beam combiner 500. Further, the first laser beam L1 and the second laser beam L2 combined by the beam combiner 500 may be light-collected on the object to be processed through the light-collecting lens 600.

Further, the laser scribing device 10 may include a plurality of mirror parts M1 and M2 for changing the light path of the laser. As a result, a size of the laser scribing device 10 is capable of being reduced.

Hereinafter, the laser scribing device 10 according to the first embodiment of the present disclosure is described in detail with reference to FIG. 1.

The P-polarized laser beam output from the laser light source 100 is output to the splitter 200. The splitter 200 may divide the P-polarized laser beam output from the laser light source 100 into the P-polarized first laser beam L1 and the P-polarized second laser beam L2.

Further, the P-polarized first laser beam L1 is output to the first wave plate 320 by the first mirror part M1, and passes through the first wave plate 320, and thus a polarization state of the P-polarized first laser beam L1 is changed to a S-polarized first laser beam L1. Further, the divergent angle of the first laser beam L1 incident on the light-collecting lens 600 may be adjusted by the beam expander telescope 400 positioned on the path of the first laser beam L1. In addition, the S-polarized first laser beam L1 passing through the beam expander telescope 400 may be reflected by the second mirror part M2 and output to the beam combiner 500. In addition, the first wave plate 320 and the beam expander telescope 400 may be positioned on the path of the second laser beam L2.

In addition, the S-polarized first laser beam L1 and the P-polarized second laser beam L2 may be combined with each other while passing through the beam combiner 500. In other words, the S-polarized first laser beam L1 and the P-polarized second laser beam L2 may be positioned on the same path by the beam combiner 500. Further, the S-polarized first laser beam L1 may be irradiated to the first focus F1 through the light-collecting lens 600 and the P-polarized second laser beam L2 may be irradiated to the second focus F2 through the light-collecting lens 600.

That is, the laser scribing device 10 generates the first laser beam L1 and the second laser beam L2 having different focal distances, and forms focuses having different heights in the thickness direction inside the object to be processed. For example, when the first laser beam L1 is diverged by the beam expander telescope 400, the first laser beam L1 forms the first focus F1 below the second focus F2 of the second laser beam L2 within the object to be processed. On the contrary, when the first laser beam L1 is converged by the beam expander telescope 400, the first laser beam L1 forms the first focus F1 above the second focus F2 of the second laser beam L2 within the object to be processed.

Further, in a state in which the laser beam is focused on the light-collecting point within the object to be processed, the laser beam or the object to be processed is moved along a first direction. Thus, internal cracks are formed inside the object to be processed. In other words, when the laser beams L1 and L2 are moved along a line on which the object to be processed is cut, first and second internal cracks may be simultaneously formed at upper and lower portions in the object to be processed by the first and second laser beams L1 and L2.

With reference to FIG. 2, the laser scribing device 10 according to the second embodiment of the present disclosure is described.

In the laser scribing device 10 according to the second embodiment of the present disclosure, unlike the first embodiment, the beam expander telescope 400 is positioned on the path of the second laser beam L2.

In other words, the divergent angle of the second laser beam L2 incident on the light-collecting lens 600 through the beam expander telescope 400 may be adjusted. For example, when the second laser beam L2 is diverged by the beam expander telescope 400, the second laser beam L2 forms the second focus F2 below the first focus F1 of the first laser beam L1 within the object to be processed. On the contrary, when the second laser beam L2 is converged by the beam expander telescope 400, the second laser beam L2 forms the second focus F2 above the first focus F1 of the first laser beam L1 within the object to be processed. Further, the first wave plate 320 may be positioned on the second laser beam L2, and the beam expander telescope 400 may be positioned on the first laser beam L1.

With reference to FIG. 3, the laser scribing device 10 according to the third embodiment of the present disclosure is described.

In the laser scribing device 10 according to the third embodiment of the present disclosure, the beam expander telescope 400 is positioned on the path of the first laser beam L1 and the path of the second laser beam L2, respectively.

In other words, the divergent angle of the first laser beam L1 incident on the light-collecting lens 600 may be adjusted by the beam expander telescope 400 positioned on the path of the first laser beam L1, and the divergent angle of the second laser beam L2 incident on the light-collecting lens 600 may be adjusted by the beam expander telescope 400 positioned on the path of the second laser beam L2. Thus, the first laser beam L1 and the second laser beam L2 may bring the object to be processed into focus at a desired position by the user, respectively. Accordingly, the laser scribing device 10 according to the third embodiment of the present disclosure may irradiate the first laser beam L1 and the second laser beam L2 having different focal distances according to the thickness of the object to be processed. Further, the first wave plate 320 may be positioned on the path of the first laser beam L1 or the second laser beam L2.

Hereinafter, the laser scribing device 10 according to the fourth to tenth embodiments of the present disclosure is described with reference to FIGS. 4 to 10.

The laser scribing device 10 according to the fourth to tenth embodiments of the present disclosure may further include at least one of the damper 700 and the second wave plate 330. Here, the damper 700 may be a polarizer or an attenuator including an analyzer or a polarized beam splitter. For reference, the laser scribing device 10 according to the fourth to tenth embodiments of the present disclosure shown in FIGS. 4 to 10 includes at least one of the damper 700 and the second wave plate 330 based on the first embodiment of the present disclosure. However, the present disclosure is not limited to the above-described cases, and at least one of the damper 700 and the second wave plate 330 may be provided in the second embodiment or the third embodiment.

With reference to FIG. 4, the laser scribing device 10 according to the fourth embodiment of the present disclosure may further include a polarizer (not shown) coupled to an output terminal of the first wave plate 320 and controlling energy of the first laser beam L1. Here, the energy of the first laser beam L1 may be adjusted according to an angle between a polarization direction of the beam transmitted through the first wave plate 320 and a polarization direction of the polarizer.

An intensity of the beam transmitted through the damper may be expressed by Malus's Law as follows. The above-s described damper may include, but is not limited to, the first wave plate 320 and the polarizer.

I(θ)≈I(0)cos²θ [Equation 1]

in Equation 1,

I(0) is an intensity of the beam incident on the polarizing plate, and

θ is an angle between a polarization direction of the beam transmitted through the wave plate and a polarization direction of the polarizing plate.

Here, when the polarization direction of the beam transmitted through the wave plate and the polarization direction of the polarizing plate are the same, the angle is 0 degree.

With reference to FIG. 5, the laser scribing device 10 according to the fifth embodiment of the present disclosure may further include a damper 700 positioned on the path of the second laser beam L2 and controlling the energy of the second laser beam L2. For example, the damper 700 may be configured with a form or an attenuator including a wave plate (not shown) and a polarizer (not shown) adjusting the polarization state of the second laser beam L2. Here, the energy of the second laser beam L2 may be controlled according to the polarization angle of the wave plate of the damper 700 and the setting state of the polarizer. In detail, the wave plate of the damper 700 is formed by alternately forming a plurality of grooves formed in the vertical direction so that only the laser beam passing through the grooves is passed, thereby obtaining a laser having a wavelength in a vertical direction, and when rotating an angle of the wave plate of the damper 700, a ratio of a horizontally polarized laser beam and a vertically polarized laser beam may be adjusted according to the angle.

With reference to FIG. 6, the laser scribing device 10 according to the sixth embodiment of the present disclosure may further a second wave plate 330 coupled to an output terminal of the beam combiner 500 and adjusting a polarization state of the first laser beam L1 and the second laser beam L2 to a circular polarization state. For example, the second polarizing plate 330 may be a quarter wave plate, and each different linearly polarized light of the first laser beam L1 and the second laser beam L2 may be changed to the same circularly polarized light. For reference, ⊚ shown in FIG. 6 means the circularly polarized light.

With reference to FIG. 7, the laser scribing device 10 according to the seventh embodiment of the present disclosure may further include a damper 700 coupled to an output terminal of the first wave plate 320 and controlling energy of the first laser beam L1, and a damper 700 positioned on the path of the second laser beam L2 and controlling energy of the second laser beam L2.

With reference to FIG. 8, the laser scribing device 10 according to the eighth embodiment of the present disclosure may further include a damper 700 positioned on the path of the second laser beam L2 and controlling the energy of the second laser beam L2, and a second wave plate 330 coupled to an output terminal of the beam combiner 500 and adjusting a polarization state of the first laser beam L1 and the second laser beam L2 to a circular polarization state. In other words, the second laser beam L2 of which energy is controlled by the damper 700 and the first laser beam L1 may be adjusted to the circular polarization state by the second wave plate 330.

With reference to FIG. 9, the laser scribing device 10 according to the ninth embodiment of the present disclosure may further include a damper 700 coupled to an output terminal of the first wave plate 320 and controlling energy of the first laser beam L1, and a second wave plate 330 coupled to an output terminal of the beam combiner 500 and adjusting a polarization state of the first laser beam L1 and the second laser beam L2 to a circular polarization state. In other words, the energy of the first laser beam L1 may be adjusted by the damper 700. In addition, the polarization state of the first laser beam L1 of which energy is controlled and the second laser beam L2 may be adjusted by the second wave plate 330, and thus the laser beam in the circular polarization state may be irradiated.

With reference to FIG. 10, the laser scribing device 10 according to the tenth embodiment of the present disclosure may further include a damper 700 coupled to an output terminal of the first wave plate 320 and controlling energy of the first laser beam L1, a damper 700 positioned on the path of the second laser beam L2 and controlling energy of the second laser beam L2, and a second wave plate 330 coupled to an output terminal of the beam combiner 500 and adjusting a polarization state of the first laser beam L1 and the second laser beam L2 to a circular polarization state. In other words, the laser scribing device 10 according to the tenth embodiment of the present disclosure may control the energy of the first laser beam L1 and the second laser beam L2 through the damper 700. In addition, the polarization state of the first laser beam L1 of which energy is controlled and the second laser beam L2 may be adjusted by the second wave plate 330, and thus the laser beam in the circular polarization state may be irradiated.

Hereinafter, the laser scribing device 10 according to the eleventh to twentieth embodiments of the present disclosure is described with reference to FIGS. 11 to 20.

In the laser scribing device 10 according to the eleventh to twentieth embodiments of the present disclosure, the polarization state of the laser beam output to the splitter 200 may be a circularly polarized light, and the splitter 200 may be a polarized beam splitter. In other words, when the circularly polarized laser beam emitted from the laser light source 100 passes through the splitter 200 which is the polarized beam splitter, the laser beam may be divided into the S-polarized first laser beam L1 and the P-polarized second laser beam L2. In other words, in the eleventh to twentieth embodiments of the present disclosure, the first wave plate 320 is not required, unlike the first to tenth embodiments.

With reference to FIG. 11, the laser scribing device 10 according to the eleventh embodiment of the present disclosure is described.

In the laser scribing device 10 according to the eleventh embodiment of the present disclosure, the divergent angle of the S-polarized first laser beam L1 incident on the light-collecting lens 600 may be adjusted by the beam expander telescope 400 positioned on the path of the first laser beam L1. In addition, the S-polarized first laser beam L1 and the P-polarized second laser beam L2 may be combined with each other while passing through the beam combiner 500.

In other words, the S-polarized first laser beam L1 and the P-polarized second laser beam L2 may be positioned on the same path by the beam combiner 500. Further, the S-polarized first laser beam L1 may be irradiated to the first focus F1 through the light-collecting lens 600 and the P-polarized second laser beam L2 may be irradiated to the second focus F2 through the light-collecting lens 600.

With reference to FIG. 12, the laser scribing device 10 according to the twelfth embodiment of the present disclosure is described.

In the laser scribing device 10 according to the twelfth embodiment of the present disclosure, unlike the eleventh embodiment, the beam expander telescope 400 is positioned on the path of the second laser beam L2.

In other words, the divergent angle of the second laser beam L2 incident on the light-collecting lens 600 through the beam expander telescope 400 may be adjusted.

With reference to FIG. 13, the laser scribing device 10 according to the thirteenth embodiment of the present disclosure is described.

In the laser scribing device 10 according to the thirteenth embodiment of the present disclosure, the beam expander telescope 400 is positioned on the path of the first laser beam L1 and the path of the second laser beam L2, respectively.

In other words, the divergent angle of the first laser beam L1 incident on the light-collecting lens 600 may be adjusted by the beam expander telescope 400 positioned on the path of the first laser beam L1, and the divergent angle of the second laser beam L2 incident on the light-collecting lens 600 may be adjusted by the beam expander telescope 400 positioned on the path of the second laser beam L2. Thus, the first laser beam L1 and the second laser beam L2 may bring the object to be processed into focus at a desired position by the user, respectively. Accordingly, the laser scribing device 10 according to the thirteenth embodiment of the present disclosure may irradiate the first laser beam L1 and the second laser beam L2 having different focal distances according to the thickness of the object to be processed.

Hereinafter, the laser scribing device 10 according to the fourteenth to twentieth embodiments of the present disclosure is described with reference to FIGS. 14 to 20.

The laser scribing device 10 according to the fourteenth to twentieth embodiments of the present disclosure may include at least one of the damper 700 and the second wave plate 330. For reference, the laser scribing device 10 according to the fourteenth to twentieth embodiments of the present disclosure shown in FIGS. 14 to 20 includes at least one of the damper 700 and the second wave plate 330 based on the eleventh embodiment of the present disclosure. However, the present disclosure is not limited to the above-described cases, and at least one of the damper 700 and the second wave plate 330 may be provided in the twelfth embodiment or the thirteenth embodiment.

With reference to FIG. 14, the laser scribing device 10 according to the fourteenth embodiment of the present disclosure may further include a damper 700 controlling energy of the first laser beam L1 on the path of the first laser beam L1.

With reference to FIG. 15, the laser scribing device 10 according to the fifteenth embodiment of the present disclosure may further include a damper 700 positioned on the path of the second laser beam L2 and controlling energy of the second laser beam L2.

With reference to FIG. 16, the laser scribing device 10 according to the sixteenth embodiment of the present disclosure may further a second wave plate 330 coupled to an output terminal of the beam combiner 500 and adjusting a polarization state of the first laser beam L1 and the second laser beam L2 to a circular polarization state. For example, the second polarizing plate 330 may be a quarter wave plate, and each different linearly polarized light of the first laser beam L1 and the second laser beam L2 may be changed to the same circularly polarized light. For reference, ⊚ shown in FIG. 16 means the circularly polarized light.

With reference to FIG. 17, the laser scribing device 10 according to the seventeenth embodiment of the present disclosure may further include a damper 700 positioned on the path of the first laser beam L1 and controlling the energy of the first laser beam L1, and a damper 700 positioned on the path of the second laser beam L2 and controlling the energy of the second laser beam L2. In other words, the energy of the first laser beam L1 and the second laser beam L2 may be controlled by the damper 700.

With reference to FIG. 18, the laser scribing device 10 according to the eighteenth embodiment of the present disclosure may further include a damper 700 positioned on the path of the first laser beam L1 and controlling the energy of the first laser beam L1, and a second wave plate 330 coupled to an output terminal of the beam combiner 500 and adjusting a polarization state of the first laser beam L1 and the second laser beam L2 to a circular polarization state. In other words, the first laser beam L1 of which energy is controlled by the damper 700 and the second laser beam L2 may be adjusted to the circular polarization state by the second wave plate 330.

With reference to FIG. 19, the laser scribing device 10 according to the nineteenth embodiment of the present disclosure may further include a damper 700 positioned on the path of the second laser beam L2 and controlling the energy of the second laser beam L2, and a second wave plate 330 coupled to an output terminal of the beam combiner 500 and adjusting a polarization state of the first laser beam L1 and the second laser beam L2 to a circular polarization state. In other words, the energy of the second laser beam L2 may be controlled by the damper 700. In addition, the polarization state of the first laser beam L1 and the second laser beam L2 of which energy is controlled may be adjusted by the second wave plate 330, and thus the laser beam in the circular polarization state may be irradiated.

With reference to FIG. 20, the laser scribing device 10 according to the twentieth embodiment of the present disclosure may further include a damper 700 positioned on the path of the first laser beam L1 and controlling the energy of the first laser beam L1, a damper 700 positioned on the path of the second laser beam L2 and controlling the energy of the second laser beam L2, and a second wave plate 330 coupled to an output terminal of the beam combiner 500 and adjusting a polarization state of the first laser beam L1 and the second laser beam L2 to a circular polarization state. In other words, the laser scribing device 20 according to the twentieth embodiment of the present disclosure may control the energy of the first laser beam L1 and the second laser beam L2 through the damper 700. In addition, the polarization state of the first laser beam L1 of which energy is controlled and the second laser beam L2 may be adjusted by the second wave plate 330, and thus the laser beam in the circular polarization state may be irradiated.

FIG. 21 is an image of an internal crack line formed inside a substrate using the laser scribing device 10 of the present disclosure.

As shown in FIG. 21, the laser scribing device 10 may form the crack line with a sufficient thickness even in an object to be processed with 200 pm or more, proving that a thick object to be processed is capable of being scribed.

According to the present disclosure, the laser beam output from the laser light source may be divided into two laser beams using the splitter, the divided first laser beam and the divided second laser beam may be irradiated to one light-collecting lens, and the first laser beam and the second laser beam having different focal distances may be irradiated in the vertical direction to the inside of the object to be processed by one focusing, thereby cutting a thick wafer.

The above-described description of the present disclosure is provided for illustrative purposes, and it will be understood to those skilled in the art that the exemplary embodiments can be easily modified into various specific forms without changing the technical spirit or essential features of the present disclosure. Therefore, it should be understood that the above-described embodiments are not restrictive but are illustrative in all aspects. For example, each element described as a single type may be distributed and implemented, and components described as being distributed may also be implemented in a combined form.

It should be interpreted that the scope of the present disclosure is defined by the following claims rather than the above-described detailed description, and all modifications or alterations deduced from the meaning, the scope, and equivalences of the claims are included in the scope of the present disclosure.

What is claimed is:

1. A laser scribing device comprising:
a laser light source for outputting a laser beam;
a splitter for dividing the laser beam into a first laser beam and a second laser beam;
a beam expander telescope for adjusting a divergent angle on a path of the first laser beam or a path of the second laser beam;
a beam combiner for combining the first laser beam and the second laser beam; and
a light-collecting lens for light-collecting the first and second laser beams that are combined by the beam combiner,
wherein the first laser beam and the second laser beam have different focal distances.

2. The laser scribing device of claim 1, further comprising:
a damper positioned on the path of the second laser beam and controlling energy of the second laser beam.

3. The laser scribing device of claim 2, further comprising:
a damper coupled to an output terminal of a first wave plate and controlling energy of the first laser beam.

4. The laser scribing device of claim 2, further comprising:
a second wave plate coupled to an output terminal of the beam combiner and adjusting a polarization state of the first laser beam and the second laser beam to a circular polarization state.

5. The laser scribing device of claim 3, further comprising:
a second wave plate coupled to an output terminal of the beam combiner and adjusting a polarization state of the first laser beam and the second laser beam to a circular polarization state.

6. The laser scribing device of claim 2, wherein the damper includes a wave plate for adjusting a polarization state of the second laser beam, and a polarizer or an attenuator coupled to an output terminal of the wave plate and controlling energy of the second laser beam.

7. The laser scribing device of claim 1, further comprising:
a polarizer coupled to an output terminal of a first wave plate and controlling energy of the first laser beam.

8. The laser scribing device of claim 7, further comprising:
a second wave plate coupled to an output terminal of the beam combiner and adjusting a polarization state of the first laser beam and the second laser beam to a circular polarization state.

9. The laser scribing device of claim 1, further comprising:
a second wave plate coupled to an output terminal of the beam combiner and adjusting a polarization state of the first laser beam and the second laser beam to a circular polarization state.

10. The laser scribing device of claim 1, further comprising:
a first wave plate positioned on the path of the first laser beam or the path of the second laser beam divided by the splitter and rotating a polarization direction of the first laser beam or the second laser beam by 90 degrees.
